(19) United States
(12) Patent Application Publication
(10) Pub. No.: US 2021/0068301 A1
(43) Pub. Date: Mar. 4, 2021

(54) ELECTRICAL CONNECTOR AND ELECTRONIC DEVICE

(71) Applicant: PHOENIX CONTACT GmbH & Co. KG, Blomberg (DE)

(72) Inventors: Andreas Engel, Schieder-Schwalenberg (DE); Michael Mosler, Bad Pyrmont (DE); Sebastian Witte, Hameln (DE)

(21) Appl. No.: 16/964,836

(22) PCT Filed: Jan. 28, 2019
(86) PCT No.: PCT/EP2019/051984

§ 371 Date: Jul. 24, 2020

(30) Foreign Application Priority Data
Jan. 26, 2018 (DE) 102018101779.0

(51) Int. Cl. H05K 7/20; H02B 1/56; H02B 1/48

(52) U.S. Cl. CPC H05K 7/20172; H02B 1/052; H02B 1/48; H02B 1/56

(57) ABSTRACT

A plug connector includes a plug connector housing which has an input for connecting a supply voltage, and an output for forwarding the supply voltage to a consumer of an electronic device. The plug connector housing is configured to be plugged into a voltage supply plug-in location of a device housing of the electronic device in order to provide a voltage supply connection of the electronic device. The plug connector housing has a seat for inserting a blower.

The present invention relates to a plug connector and an electronic device having such a plug connector.

For the development of housings for electronic devices, a standardization of the housings is sought in order to be able to use an existing housing for a multiplicity of different devices.

In order to ensure a reliable operation of electronic devices, active cooling by means of blowers is frequently required.

For this purpose, it is known to firmly integrate a blower in the structure of a device housing. This is advantageous because such an internal blower is accommodated in a compact manner within the installation space of the device housing. However, it is disadvantageous that the blower, in case of a defect, can usually only be replaced or repaired with great expenditure. It is thus possible for the lifespan of the blower to overall limit the lifespan of the electronic device because a replacement of a defect blower is not cost-effective.

It is further known to subsequently install blowers on a device housing of an electronic device. For this purpose, a blower can be screwed or clamped to an outer side of a housing wall and wired externally via cable clamps. In such case, it is disadvantageous that such retrofitting solutions are frequently seen as makeshift solutions by the end customer and can also be easily damaged by the external components.

Against this background, the technical problem addressed by the invention is that of making an improved structural integration of a blower in an electronic device possible, wherein a blower can be integrated in an electronic device or fastened to an electronic device particularly in a retrofittable, replaceable, and compact manner.

The technical problem described above is solved respectively by a plug connector according to claim 1 and an electronic device according to claim 8. Further embodiments of the invention are disclosed in the dependent claims and the description below.

According to a first aspect, the invention relates to a plug connector having a plug connector housing with an input for connecting a supply voltage and an output for forwarding the supply voltage to a consumer of an electronic device, wherein the plug connector housing can be plugged into a voltage supply plug-in location of a device housing of the electronic device in order to provide a voltage supply connection of the electronic device, and wherein the plug connector housing has a seat for inserting a blower.

As a result, a blower can be installed together with a plug connector designed as a supply voltage connection on a device housing of an electronic device. Therefore, no additional holders for fastening the blower on the device housing are required. The voltage supply plug-in location of a device housing can thus be used simultaneously for mechanically fastening the plug connector housing and the blower installable therein.

According to a development of the plug connector, a blower is inserted into the seat and detachably connected to the seat. This allows for a cost-effective replacement of the blower.

It can be provided that, independently from a blower installed in the seat, the plug connector is designed for an interruption-free voltage supply of an electronic device. As a result, a blower can be inserted and/or removed during the actual operation of the device without resulting in an interruption of the voltage supply.

A blower connection to the voltage supply of the blower can be provided, wherein a voltage supply of the blower is diverted within the plug connector housing from the supply voltage of the electronic device.

The blower connection can be designed as a plug connector, thus allowing for a quick separation and connection of the voltage supply of the blower.

The plug connector can have a diagnostic circuit that is designed to monitor a power consumption of the blower. As a result, overloading of and damage to an upstream power supply unit, which supplies the blower and the electronic device, can be prevented if, e.g., a short circuit occurs on the blower. Therefore, the diagnostic circuit can particularly be designed to monitor a blower operation in its intended nominal operating range.

The plug connector can comprise a diagnosis and/or status display which indicates an operating state and/or a need for maintenance using light signals, wherein the diagnosis and/or status display has one or more LED light sources, wherein one or more LED light sources are single- or multicolored.

The diagnostic circuit can be connectable to the electronic device, so that a diagnostic signal of the diagnostic circuit is forwarded to the electronic device.

For example, the diagnostic signal can be forwarded via an electromechanical connection to a consumer of the electronic device. Alternatively or additionally, the diagnostic signal can be modulated to an operating voltage supplied to a consumer of the electronic device.

Alternatively or additionally, an interface can be associated with the diagnostic circuit in order to transmit a status of the blower in a wireless and/or wired manner. For example, for this purpose, a LAN or W-LAN interface can be used. Bluetooth, infrared or other wireless or wired standards for data and/or signal transmission can naturally also be used.

A further design of the plug connector is characterized in that the input and the output are spaced apart from a mechanical fastener designed for mechanically fastening the plug connector housing in the voltage supply plug-in location of the device housing of the electronic device. As a result, good accessibility of the input and the output can be assured in a simple manner in order to apply or clamp lines to the input and output.

The fastener can comprise a latching or snap-in connection in order to ensure an interlocking and force-locking fastening. The fasteners can comprise form elements designed for engaging in and/or receiving complementarily formed fasteners of the device housing.

According to a second aspect, the invention relates to an electronic device having a device housing, with a consumer accommodated in the device housing, with a voltage supply plug-in location provided on the device housing for receiving a plug connector, wherein a plug connector is accommodated in the voltage supply plug-in location in order to provide a voltage supply connection of the electronic device, and wherein the plug connector is designed in a manner according to the invention.

As a result, a blower, together with the plug connector designed as a supply voltage connection, can be installed on the device housing of the electronic device. Therefore, no additional holders for fastening the blower on the device housing are required. The voltage supply plug-in location of the device housing can thus be used simultaneously for mechanically fastening the plug connector housing and the blower installable therein.

It can be provided that a blower is accommodated in the seat, wherein the blower is flush with at least one side of the device housing and/or is arranged at least in sections to be set back with regard to a sidewall of the device housing. The blower can be thus be integrated in the device housing or arranged on the device housing in a compact manner.

A further design of the electronic device is characterized in that the device housing is designed for an interlocking and/or force-locking fastening on a support rail of a switchgear cabinet. The device housing can, e.g., have a seat for fastening to a top-hat rail and/or movable or rigid clamping elements or snap-in elements for fastening to a top-hat rail.

It can be provided that the electronic device is installed or held in an interlocking and/or force-locking manner within a switchgear cabinet.

According to a further design of the electronic device, it is provided that the device housing has at least one opening for an air exchange between a housing interior and an environment, wherein the blower is associated with the opening, particularly faces said opening, in order to generate an air volume flow between the housing interior and the environment.

During blower operation, it is therefore particularly provided that the consumers within the device housing are cooled by means of an air flow which flows through the housing interior and is generated by the blower.

The blower can be designed to blow air into the device housing or suction air out of the device housing via the opening.

The device housing can have two or more openings.

One opening of the device housing can be slit-shaped. A plurality of slit-shaped device openings can be provided on the housing.

In the following, the invention shall be described in more detail using drawings showing embodiments. It is schematically shown in:

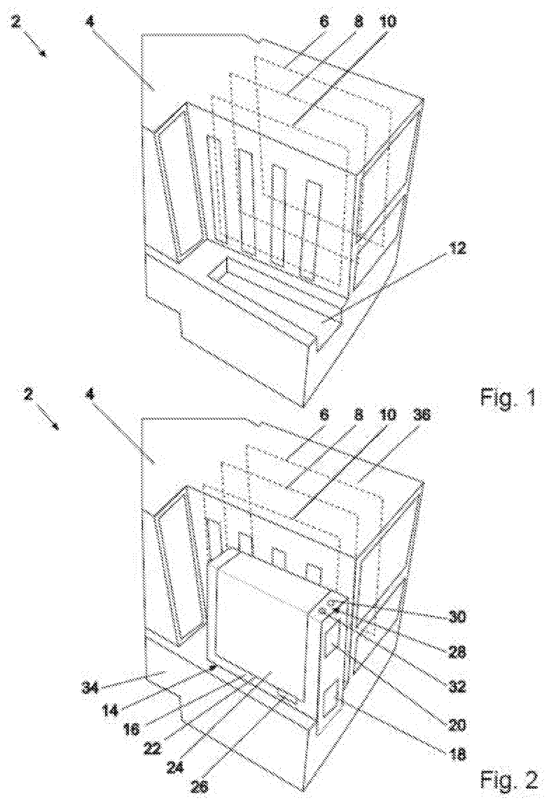

FIG. 1 a perspective view from above of a partial section of an electronic device;

FIG. 2 the electronic device from FIG. 1 with a plug connector and installed blower;

FIG. 1 shows a partial section of an electronic device 2 according to the invention, having a device housing 4, in which a plurality of consumers 6, 8, 10 are accommodated. The device housing 4 has a voltage supply plug-in location 12 which is designed to receive a plug connector according to the invention.

FIG. 2 shows the electronic device 2 from FIG. 1, wherein a plug connector 14 according to the invention is accommodated in the voltage supply plug-in location 12. The plug connector 14 has a plug connector housing 16. The plug connector housing 16 has an input 18 for connecting a supply voltage, wherein a power supply unit can be connected to the input 18.

The plug connector housing 16 has an output 20 for forwarding the supply voltage to the consumers 6, 8, 10 of the electronic device 2. According to alternative designs of the invention, the output 20 can naturally also be arranged on an underside or a rear side of the plug connector housing 16.

The plug connector housing 16 has a seat 22, in which the blower 24 is inserted. In the present case, the blower 24 is held detachably in the seat 22.

Independently from a blower 24 installed in the seat 22, the plug connector 14 is designed for an interruption-free voltage supply of the electronic device 2 or the consumers 6, 8, 10.

The plug connector 14 has a blower connection 26 for the voltage supply of the blower 24, wherein a voltage supply of the blower 24 is diverted within the plug connector housing 16 from the supply voltage of the electronic device 2 or the consumers 6, 8, 10.

The plug connector 14 comprises a diagnostic circuit (not depicted) which is designed to monitor a power consumption of the blower 24.

The plug connector 14 further comprises a diagnosis and/or status display 28 which indicates an operating state and/or a need for maintenance using light signals, wherein the diagnosis and/or status display 28 has LED light sources 30, 32 which are multicolored.

The diagnostic circuit is connectable to the electronic device 2 or a consumer 6, 8, 10.

The blower 24 is arranged to be set back with regard to sidewalls 34, 36 of the device housing.

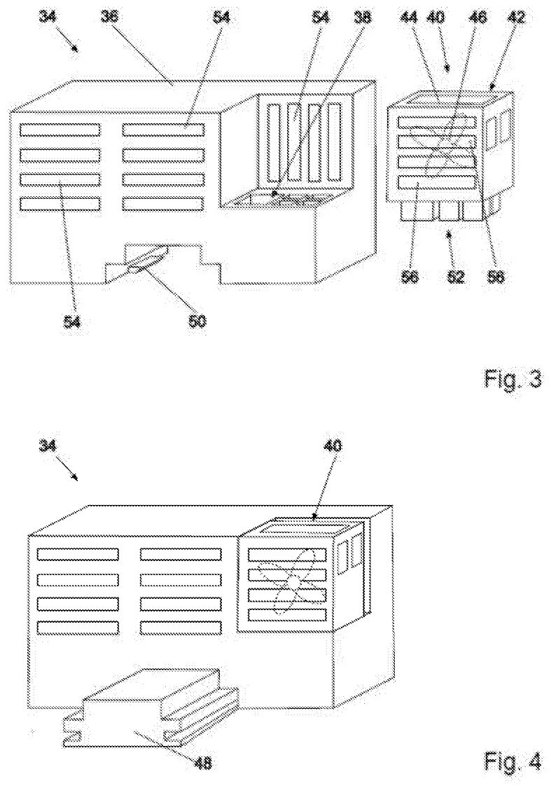

FIG. 3 shows a perspective view of a further electronic device 34 according to the invention which comprises a device housing 36, in which a plurality of consumers are accommodated. The device housing 34 has a voltage supply plug-in location 38 which is designed to receive a plug connector 40 according to the invention.

FIG. 4 shows the electronic device 34 from FIG. 1, wherein the plug connector 40 according to the invention is accommodated in the voltage supply plug-in location 38. The plug connector 40 has a plug connector housing 42.

The plug connector housing 42 has a seat 44, into which a blower 46 is inserted. In the present case, the blower 46 is held detachably in the seat 44.

Independently from a blower 46 installed in the seat 44, the plug connector 40 is designed for an interruption-free voltage supply of the electronic device 34 or the consumers.

The device housing 36 is designed for an interlocking and force-locking fastening on a support rail 48 of a switchgear cabinet (FIG. 4). For this purpose, snap-in elements 50 are provided.

The device housing 36 has openings 54 for an air exchange between a housing interior and an environment U. The blower 46 generates an air volume flow between the housing interior and the environment U. The plug connector housing 42 also has openings 56 for an air exchange, so that an air volume flow through the plug connector housing 42, which surrounds the blower 46, can be conveyed toward the device housing interior or from the device housing interior in order to effect a cooling of the consumers.

The voltage supply plug-in location 38 has six recesses which, in the fully installed state, engage in the protrusions 52 of the plug connector housing 42. The protrusions 52 can be mechanically locked in place in the area of the recesses. In the area of the recesses, electrical contacts can be formed between the protrusions 52 and the device housing 36 in order to supply the consumer and/or the blower with an operating voltage.

### REFERENCE SIGNS

2, 34 Electronic device

4, 36 Device housing

6 Consumer

8 Consumer

10 Consumer

12, 38 Voltage supply plug-in location

14, 40 Plug connector

16, 42 Plug connector housing

18 Input

20 Output

22, 44 Seat

24, 46 Blower

26 Blower connection

28 Diagnosis and/or status display

30 LED light sources

32 LED light sources

48 Support rail

50 Snap-in element

52 Protrusions

54 Opening

56 Opening

U Environment

1. A plug connector comprising:
a plug connector housing which includes:
an input for connecting a supply voltage, and
an output for forwarding the supply voltage to a consumer of an electronic device,
wherein the plug connector housing is configured to be plugged into a voltage supply plug-in location of a device housing of the electronic device in order to provide a voltage supply connection of the electronic device, and
wherein the plug connector housing further includes a seat for inserting a blower.

2. The plug connector according to claim 1, wherein the blower is inserted in the seat and detachably connected to the seat.

3. The plug connector according to claim 2, wherein, independently from the blower inserted in the seat, the plug connector provides an interruption-free voltage supply to the electronic device.

4. The plug connector according to claim 1:
wherein a blower connection is provided for a voltage supply of the blower, and
wherein the voltage supply of the blower is diverted within the plug connector housing from the supply voltage of the electronic device.

5. The plug connector according to claim 2, further comprising a diagnostic circuit configured to monitor a power consumption of the blower.

6. The plug connector according to claim 5, wherein:
a diagnosis and/or status display is provided which indicates an operating state and/or a need for maintenance using light signals,
wherein the diagnosis and/or status display has one or more LED light sources, and
wherein the one or more LED light sources are single- or multicolored.

7. The plug connector according to wherein:
the diagnostic circuit is connectable to the electronic device or a consumer, and/or
an interface is associated with the diagnostic circuit in order to transmit a status of the blower via a wireless and/or wired connection.

8. The plug connector according to claim 1, wherein the input and the output are spaced apart from a mechanical fastener configured to mechanically fasten the plug connector housing in the voltage supply plug-in location of the device housing of the electronic device.

9. An electronic device comprising:
a device housing;
a consumer accommodated in the device housing; and
a voltage supply plug-in location provided on the device housing for receiving a plug connector,
wherein the plug connector is accommodated in the voltage supply plug-in location in order to provide a voltage supply connection of the electronic device, and
wherein the plug connector includes a plug connector housing including:
a seat for inserting a blower,
an input for connecting a supply voltage, and
an output for forwarding the supply voltage to the consumer of the electronic device, and
wherein the plug connector housing is configured to be plugged into the voltage supply plug-in location of the device housing of the electronic device to provide the voltage supply connection of the electronic device.

10. The electronic device according to claim 9, wherein the blower is accommodated in the seat, and
wherein the blower is flush with at least one sidewall of the device housing, and/or the blower is arranged at least in sections to be set back with regard to the at least one sidewall of the device housing.

11. The electronic device according to claim 9, wherein the device housing is configured for an interlocking and force-locking fastening on a support rail of a switchgear cabinet.

12. The electronic device according to claim 9, wherein the device housing has at least one opening for an air exchange between a housing interior and an environment, and
wherein the blower is associated with the opening in order to generate an air volume flow between the housing interior and the environment.
